(19) United States
(12) Patent Application Publication
(10) Pub. No.: US 2007/0227709 A1
(43) Pub. Date: Oct. 4, 2007

(54) Multi device cooling

(76) Inventors: Girish Upadhya, Austin, TX (US); Douglas E. Werner, Santa Clara, CA (US); Mark Munch, Los Altos Hills, CA (US)

Correspondence Address: HAVERSTOCK & OWENS LLP, 162 N WOLFE ROAD, SUNNYVALE, CA, 94086, US

(21) Appl. No.: 11/731,541

(22) Filed: Mar. 29, 2007

Related U.S. Application Data
(60) Provisional application No. 60/788,545, filed on Mar. 30, 2006.

(51) Int. Cl. H05K 7/20

(52) U.S. Cl. 165/121; 165/80.4; 361/699; 165/104.33

(57) ABSTRACT

A micro scale cooling system comprises a first heat exchanger thermally coupled to a first heat source. The cooling system also has a second heat exchanger thermally coupled to a second heat source and a connection between the first heat exchanger and the second heat exchanger. A fluid flows through the first and second cooling plates. The cooling system has a first pump for driving the fluid. The cooling system further includes a first radiator and tubing that interconnects the first heat exchanger, the second heat exchanger, the first pump, and the first radiator. The tubing of some embodiments is designed to minimize fluid loss. Some embodiments optionally include a first fan to reject heat from the first radiator, and/or a volume compensator for counteracting fluid loss over time. In some embodiments, at least one heat exchanger has at least one micro scale structure. Some embodiments include a method of cooling the heat sources for a multi device configuration by using such a cooling system.

### RELATED APPLICATIONS

This application claims priority under 35 U.S.C. section 119(e) of co-pending U.S. Provisional Patent Application No. 60/788,545, filed Mar. 30, 2006, and entitled “Multi Chip Cooling,” which is hereby incorporated by reference.

### FIELD OF THE INVENTION

The present invention is related to liquid cooling. More specifically, the present invention is related to methods and systems for multi device cooling.

### BACKGROUND OF THE INVENTION

In the field of cooling systems for electronics, cooling of current semiconductor chips is presenting significant challenges for traditional means of cooling, which include fan mounted heat sinks and heat pipes. For instance, modern high performance processors have very high heat dissipation requirements. However, the traditional cooling methods have a number of limitations. Fan mounted heat sinks often do not move enough air quickly enough to cool a modern processor or do not sufficiently move hot air out of the casing holding the electronics. Similarly, heat pipes are limited in the amount of heat they can dissipate, and the distance they can move the heat from the heat source. Hence, conventional cooling techniques that use heat pipes or fan mounted heat sinks are not adequate for cooling modern electronics, such as high performance processors, which often have heat dissipation requirements that exceed 100 Watts per device.

Moreover, multi processor (multi chip) configurations have particular confounding attributes. For instance, each processor in a multi processor configuration separately contributes to the operating conditions for the configuration as a whole. Hence, each processor in a dual or multi processor configuration adds to the heat “inside-the-box” within which the other processor must operate. Further, multi processor configurations are already cost constrained in the market. A costly cooling system, though effective, tends to render the cooled hardware impractical if it adds too much to the cost, or merely requires too much modification of the cooled hardware.

### SUMMARY OF THE INVENTION

A cooling system includes a first heat exchanger, a second heat exchanger, a connection between the first and second heat exchangers, a fluid, a first pump, a first radiator, a first fan, and tubing. The first heat exchanger is thermally coupled to a first heat source and the second heat exchanger is thermally coupled to a second heat source. A fluid flows through the first and second heat exchangers via the connection. The first pump is for driving the fluid. The first fan is configured to reject heat from the first radiator. The tubing interconnects the first heat exchanger, the second heat exchanger, the first pump, and the first radiator. The tubing of some embodiments is designed to minimize fluid loss. Some embodiments include additional heat exchangers, such as a third heat exchanger, for example. The cooling system is mounted substantially interior of an upper surface of the chassis. In this way, the first fan blows air through the first radiator and exterior of the chassis. The system can remove up to 600 W of heat from the chassis while producing only minimal noise and preferably no more than 35 dB of noise.

Preferably the tubing forms a closed cooling loop for the system. In some embodiments the first heat exchanger comprises a micro scale cold plate, while in some embodiments the first heat exchanger comprises a micro scale structure such as a micro channel. The cooling system of some embodiments includes a volume compensator for keeping the fluid under slight positive pressure and/or compensating for fluid loss over time. Typically, the first pump is mechanical.

In some embodiments, the connection between the first heat exchanger and the second heat exchanger is such that the first and second heat exchangers are in series, while in some embodiments the first heat exchanger and the second heat exchanger are in parallel. In additional embodiments, the cooling system further includes a second radiator, a second pump, and a second fan. For instance, in some of these embodiments, the second pump is disposed in series with the first pump, and/or the second radiator is disposed in series with the first radiator. Alternatively, the second pump is disposed in parallel with the first pump, and/or the second radiator is disposed in parallel with the first radiator.

The cooling system of some embodiments includes a cooling module that is preferably positioned on top of a computer chassis, without the need for significant modification of the computer chassis. The cooling module of some of these embodiments houses the first radiator, the first fan, and the first pump. Typically, the cooling module is organized into a slim low profile assembly, with a maximum height of approximately 120 millimeters, for example, and a length and width that are no greater than the dimensions of a computer chassis.

The first heat source comprises a central processing unit (CPU) in some embodiments, while the second heat source comprises a graphics processing unit (GPU). Alternatively, the second heat source comprises a CPU.

In some embodiments, a cooling system includes a first cooling plate, a second cooling plate, tubing, a fluid, a first radiator, a first fan, a pump, and optionally, a reservoir. The first cooling plate is adapted for use with a first processor and the second cooling plate is adapted for use with a second processor. The tubing is for interconnecting the cooling plates. The fluid flows through the cooling plates and the tubing. The first radiator is for absorbing heat from the fluid, the fan is for rejecting heat from the first radiator, the reservoir is for storing the fluid, and the first pump is for driving the fluid through the tubing and cooling plates to the first radiator.

In some embodiments, the cooling system further includes a third cooling plate adapted for use with a third processor. Preferably, the first radiator, the first pump, and the reservoir are located at strategic locations in a module which is positioned on top of a computer chassis. The module of some embodiments has a top exhaust and a side intake.

The first and second cooling plates for the first and second processors are in series, or alternatively, the first and second cooling plates for the first and second processors are in parallel. Depending on the configuration, the cooling system provides a variety of cooling efficacies, such as, for example, approximately 500-600 Watts of total heat dissipation, in some instances. In some implementations, a volumetric air displacement is approximately 50-60 cubic feet per minute. Typically, the fan operates at less than 40 dB and preferably at less than 35 dB.

The junction-to-ambient resistance (Rⱼ₋ₐ) is about 0.35 degrees Celsius per Watt for the first processor of some embodiments. The junction-to-ambient resistance (Rⱼ₋ₐ) is about 0.35 degrees Celsius per Watt for the second processor of some embodiments. The second processor is often downstream from the first processor. The cooling system dissipates approximately 185 Watts of heat from the first processor of some embodiments.

In a particular implementation, the first and second processors comprise GPU's, and in some implementations the third processor is a CPU. In some of these embodiments, the CPU cooling plate is in series with the cooling plates for the first and second processors, while in some embodiments, the CPU cooling plate is in parallel with the cooling plates for the first and second processors. A case-to-ambient resistance is about 0.20 degrees Celsius per Watt for the third processor of some embodiments, and the system dissipates about 165 Watts of heat for the third processor of these embodiments.

In some implementations, the first, second, and third cooling plates are in series. Alternatively, two of the cooling plates are in series-parallel with one of the cooling plates. Additional embodiments include a first cooling loop and a second cooling loop for one or more of the cooling plates. In some embodiments, the design of the first cooling plate is specific to a first GPU, such that a mounting configuration for the first cooling plate is customized for the first GPU. In some embodiments, the design of the third cooling plate is specific to a CPU, such that a mounting configuration of the third cooling plate is customized for the CPU.

The radiator of some embodiments further comprises a micro tube and air fins. Preferably, the design of the radiator is customized for the application of the cooling system. For instance, the radiator design of some embodiments further comprises one or more of an optimized fluid flow through a micro tube and an optimized airflow across one or more air fins. Where the fluid comprises a liquid, for example, then the flow of the liquid is optimized in these embodiments.

A method of cooling collects the heat from a first heat source in a heat exchanger, which has a fluid. The method transfers the heat to a radiator means by using the fluid, disperses the heat from the radiator means, and optionally stores the fluid in a reservoir. The heat exchanger is typically disposed in intimate contact with the first heat source.

### BRIEF DESCRIPTION OF THE DRAWINGS

FIG. 1 illustrates a cooling module mounted on top of a computer chassis.

FIG. 1A illustrates several pump configurations for some embodiments of the invention.

FIG. 1B illustrates the radiator of some embodiments.

FIG. 1C illustrates the dimensional elements of a radiator in accordance with some embodiments.

FIG. 2 illustrates a cooling module mounted on top of a computer chassis.

FIG. 3A illustrates a heat exchanger in accordance with some embodiments of the invention.

FIG. 3B illustrates the dimensional characteristics of a cooling plate heat exchanger according to some embodiments.

FIG. 4 conceptually illustrates a closed cooling loop with a series heat exchanger for each of three processor devices.

FIG. 5 conceptually illustrates a closed cooling loop with two series heat exchangers in parallel with a third heat exchanger.

FIG. 6 conceptually illustrates a closed cooling loop with a heat exchanger in series with two parallel heat exchangers.

FIG. 7 conceptually illustrates two closed cooling loops, one for GPU cooling and the other for CPU cooling.

FIG. 8 is a process flow that illustrates the method of some embodiments.

FIG. 9 illustrates a CPU type semiconductor device having a case-to-ambient heat resistance.

FIG. 10 illustrates a GPU type semiconductor device having a junction-to-ambient heat resistance.

### DETAILED DESCRIPTION OF THE INVENTION

In the following description, numerous details are set forth for purpose of explanation. However, one of ordinary skill in the art will realize that the invention may be practiced without the use of these specific details. In other instances, well-known structures and devices are shown in block diagram form in order not to obscure the description of the invention with unnecessary detail.

Overview

Some embodiments of the invention provide a closed loop liquid cooling system that has particular advantages over conventional cooling systems. These embodiments disperse heat more efficiently to the ambient environment away from a hot semiconductor device or a set of devices. The design of these novel liquid cooling systems is quite complex and pays careful consideration to a variety of factors such as airflow rate, liquid flow rate, design of specialized fins for airflow, and design of custom structures having optimized fluid flow and/or heat exchange. The custom structures are generally referred to herein as heat exchangers. Some of the heat exchangers take the form of cooling plates that are designed to couple to specific heat sources, such as semiconductor devices and/or processor chips, for example. Preferably, the cooling plates include micro and/or macro scale components such as channels for directing fluid flow over or even through the heat source. The cooling systems of some embodiments further include one or more liquid cooling module(s) in conjunction with a set of heat exchangers to cool multiple heat sources.

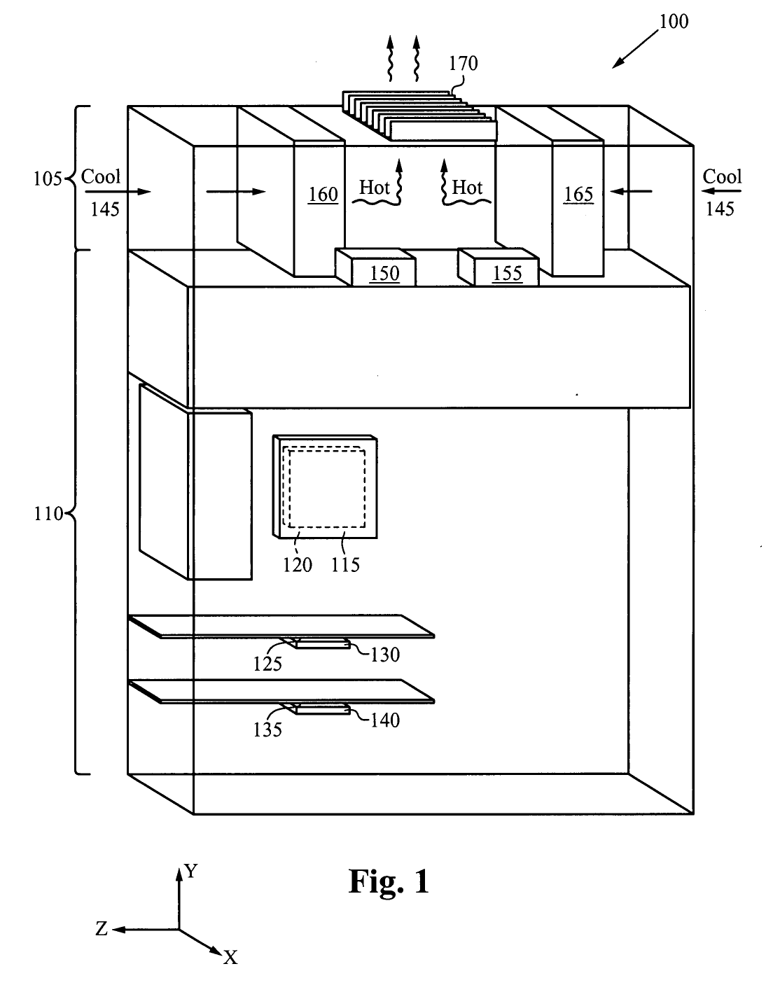

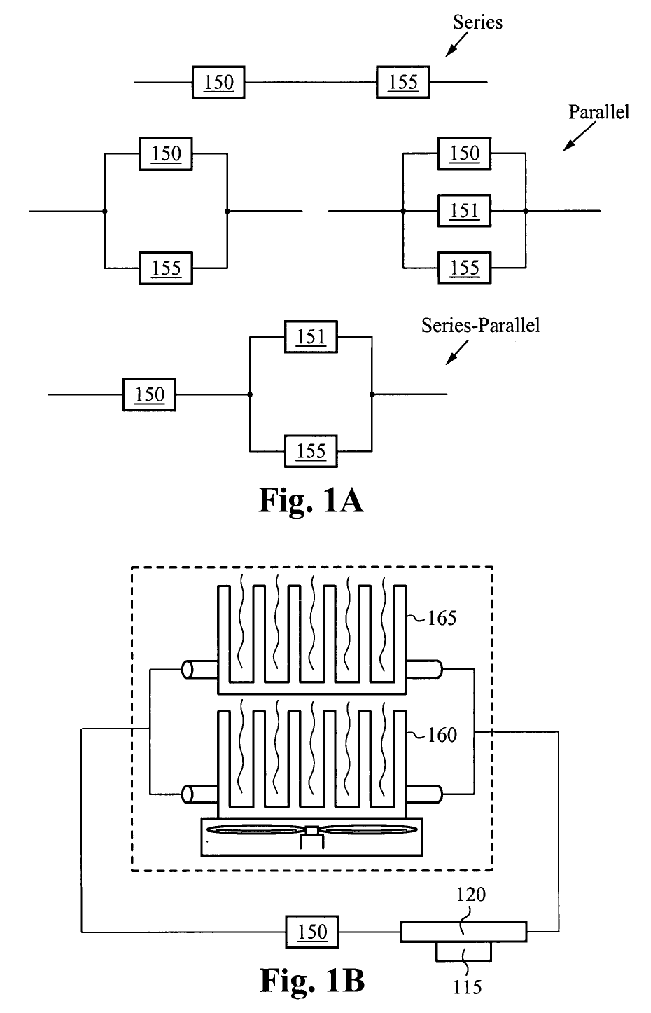

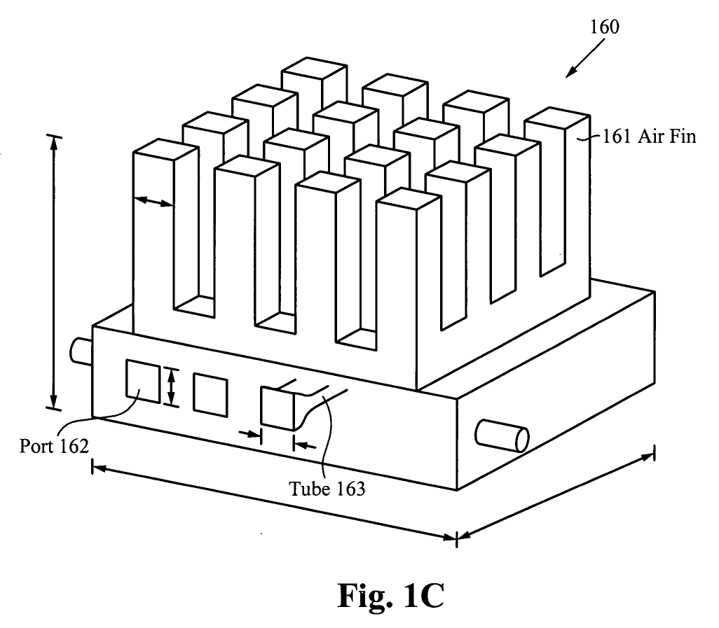

For instance, FIG. 1 illustrates a cooling system 100 in accordance with some embodiments of the invention. As shown in this figure, a cooling module 105 is mounted on top of a computer chassis 110. The computer chassis 110 has three heat sources. In this example, the exemplary heat sources are semiconductor devices including one central processing unit (CPU) 115 and two graphic processing units (GPUs) 125 and 135. Each processor 115, 125, and 135 has an associated heat exchanger 120, 130, and 140 in the shape of a cooling plate that is preferably coupled to a top surface of the processor. However, one of ordinary skill in the art recognizes that the exemplary heat exchangers 120, 130 and 140 are advantageously coupled to other semiconductor and also non semiconductor devices, such as, for example, processing units, voltage regulator modules, capacitors, resistors, and other transistive, capacitive and/or inductive type electronic components, for example, that are typical heat sources within a computer chassis. In these embodiments, the heat exchanger preferably takes on a design, shape, and/or form that is more appropriate for the specific application.

In the processor type application illustrated in FIG. 1, the (cooling plate) heat exchangers 120, 130, and 140 are typically coupled to the cooling module 105 in a closed loop by using tubing (not shown). A cooling fluid flows through the closed loop to carry heated fluid from the heat exchangers 120, 130, and 140, and transfer the heat from the fluid to the cooling module 105. The cooling module 105 typically dissipates the heat to the atmosphere outside the computer chassis 110.

The cooling module 105 contains porting for intake and exhaust, one or more pumps, one or more radiators, and one or more fans. For instance, as illustrated in FIG. 1, the cooling module 105 includes two side intakes 145, a top exhaust outlet 170, two pumps 150 and 155, and two radiators 160 and 165. The pumps 150 and 155 preferably drive heated fluid from the heat exchangers 120, 130, and 140 to the radiators 160 and 165. The pumps 150 and 155 are typically mechanical pumps that provide liquid flow rates in the range of about 0.25 to 5.0 liters per minute. However, some embodiments include a different type of pump, for example an electro-kinetic, and/or an electro-osmotic pump. U.S. Pat. No. 6,881,039 B2 entitled “Micro-Fabricated Electrokinetic Pump” and issued Apr. 19, 2005, which is hereby incorporated by reference, describes different types of pumps in greater detail. As the fluid flows through a closed cooling loop of some embodiments, the liquid pressure drops, typically in the range of about 0.5 to 5.0 pounds per square inch (PSI).

The intakes 145 and/or the exhaust 170 typically include one or more fans (not shown) that reject heat from the radiators to the ambient environment outside of the cooling module 105 and the chassis 110. Preferably, the fan(s) include a large diameter, low speed fan, such as one having, for example, about a 120 millimeter diameter. Larger, slower fans typically provide a number of cost and/or performance advantages including high volume air displacement, while permitting the use of fewer fans, that cost less, consume less power, and have quieter operation. Some implementations use only one or two low cost fans that consume less than about 130 to 140 Watts of power, while displacing the heated air within the computer chassis at an air flow rate of about 25 to 75 cubic feet per minute (CFM), and at less than about 40 decibels (dB), for example and preferably at less than 35 dB.

One of ordinary skill recognizes still further variations of the embodiment illustrated in FIG. 1, such as, alternative embodiments that employ other types and numbers of pumps. For instance, the pumps 150 and 155 are connected in series in some embodiments, while in some embodiments they are connected in parallel. FIG. 1A illustrates these series, parallel, and series-parallel configurations for the two or more pumps (150, 151, 155) of some embodiments. These pumps often act as a single pumping mechanism that is calibrated for particular volume and pressure characteristics by using the series and/or parallel arrangement of the pumps. Alternatively, some embodiments simply employ a single pump. As described below, the series and/or parallel configurations for the pumps in FIG. 1A are also adopted for other components of the cooling system. Hence, some embodiments have series and/or parallel designs for the heat exchangers and/or the radiators.

For instance, FIG. 1B illustrates an alternative configuration for a radiator according to some embodiments. As shown in this figure, the radiator of some embodiments is actually comprised of two or more radiator elements 160 and 165 disposed in parallel. Typically, the radiator elements 160 and 165 have separate fins and fluid pathways, but are housed within a single casing. This particular configuration realizes certain efficiencies, such as smaller form factor, lower cost, and a common locus for heat rejection, which further reduces the size and number of fans, and the amount of air displacement needed to reject heat from the radiators. Regardless of configuration, the radiators 160 and 165 typically have a small form factor. FIG. 1C illustrates the exemplary radiator 160 in further detail. As shown in this figure, the radiator 160 has a set of air fins 161, ports 162, and tubes 163. Each of these elements has its own set of dimensions. The dimensions of some radiators in accordance with the invention are exemplified in the following table:

| Radiator Dimension | Air fins | | Fluid tubes | | Overall form factor | |
|---|---|---|---|---|---|---|
| Width/Thickness | 0.10–0.50 | mm | 0.5–5.0 | mm | 50–150 | mm |
| | | | | | 5–25 | mm headers |
| Height | 5–15 | mm | 0.5–5.0 | mm | 40–150 | mm |
| Depth | | | | | 10–75 | mm |
| Quantity | 10–150 | fins | 2–40 | ports | | |
| | | | 2–15 | tubes | | |
| Density | 15–25 | fins/inch | | | | |

In some embodiments, the radiators 160 and 165 are fan radiators that advantageously combine a radiator with a fan in a single unit. Typically, heated fluid flows along the fins of the radiator portion. Then, the heat is rejected from the fluid by the air flow generated around the fins by the fan. Radiators and heat rejection are described in further detail in U.S. patent application Ser. No. 11/582,657, filed entitled “Cooling Systems Incorporating Microstructured Heat Exchangers,” filed Oct. 17, 2006, and entitled COOLING SYSTEMS INCORPORATING MICROSTRUCTURED HEAT EXCHANGERS which is incorporated herein by reference.

The cooling system 100 optionally includes a volume compensator and/or reservoir. The volume compensator keeps the liquid under slight positive pressure and compensates for fluid loss over time. Similarly, the tubing of some embodiments has certain features that minimize fluid loss from the closed loop system. Exemplary tubing to minimize fluid loss is disclosed in U.S. Provisional Patent Application Ser. No. 60/763,566, filed Jan. 30, 2006, and entitled TAPED-WRAPED MULTILAYER TUBING AND METHODS MAKING THE SAME, and also U.S. patent application Ser. No. 11/699,795, filed Jan. 29, 2007, and entitled TAPE-WRAPPED MULTILAYER TUBING AND METHODS MAKING THE SAME which are incorporated herein by reference.

The cooling module 105 of some embodiments is organized into a slim low profile assembly. Specifically, the cooling module 105 of some embodiments has a maximum height of approximately 120 millimeters and a length and width that does not extend beyond the dimensions of the computer chassis upon which the cooling module is mounted. Since the cooling modules of these embodiments are designed for compactness, the pump(s), fan(s), radiator(s), volume compensator and/or reservoir are typically positioned strategically within the cooling module for optimum efficiency in terms of space savings and cooling efficacy.

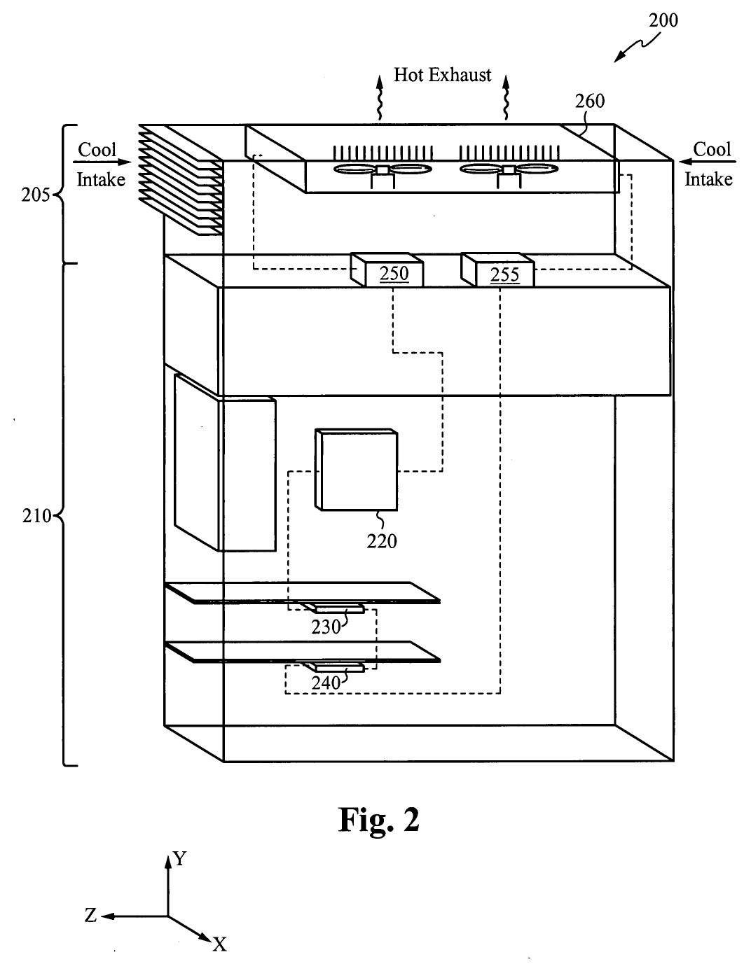

For instance, FIG. 1 illustrates one configuration for the components of the cooling module 105, while FIG. 2 illustrates an additional configuration for a module 205. More specifically, FIG. 1 illustrates the components arranged such that cool air is drawn into the cooling module 105 through the side intakes 145 by transversely mounted fans and/or radiators. The fans blow the cool air across the heated fins of the radiators and out through the exhaust outlet 170 at the top of the cooling module 105. As mentioned above, heated fluid typically flows from cooling plates 120, 130, and 140 and circulates through the fins such that the heat from the fluid is dissipated from the fins.

FIG. 2 illustrates an alternative configuration for the fans and radiators. As shown in this figure, the fans are vertically mounted with a single large radiator 260 such that the fans blow the heated air directly up and away from the computer chassis 210.

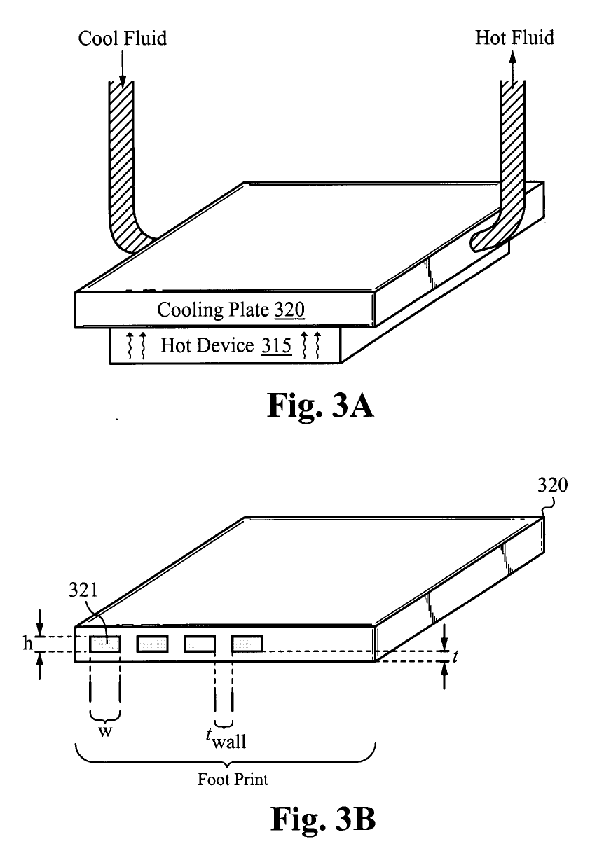

As illustrated in the figures described above, some embodiments have multiple heat exchangers in the form of cooling plates. FIG. 3A illustrates a conceptual view of the heat exchangers of some embodiments in further detail. As shown in this figure, the cooling plate 320 attaches directly to a surface of a heat source, particularly a hot processor 315. The cooling plate 320 has one or more micro scale and/or macro scale structures for the targeted delivery of cooling fluid and the removal of heat from the hot spots on and/or within the heat source. The cooling fluid typically carries heat away from the heat source, while the device is operating. Thus, the temperature of the device remains within a reasonable operating range, despite the device's high speed operation and/or high power consumption.

Moreover, the potential for hot spots is reduced, depending on the configuration and design of the heat exchanger 320. FIG. 3B illustrates a cooling plate design for the heat exchanger 320 having a feature 321 and several dimensions. In this embodiment, the feature 321 takes the form of an internal tube or channel having a height (h), a width (w), and a wall thickness (t_{wall}). Also shown in this figure, the cooling plate has a base thickness (t) and an overall foot print. As mentioned above, some embodiments have micro scale features, while some have macro scale features, and/or some embodiments have a combination of micro and macro scale features, to direct fluid flow within the heat exchanger. For instance, some embodiments have features that affect the direction, pressure, and/or the volume of fluid flow. As used herein, micro scale features are smaller than macro scale features by a predetermined factor. Hence, the dimensions that distinguish a micro scale feature from one that is macro is as follows, in some embodiments:

| heat exchanger feature | | |
|---|---|---|
| (all in millimeters) | micro scale | macro scale |
| width (w) | 0.05–0.25 mm | 0.75–2.00 mm |
| height (h) | 0.30–1.00 mm | 2.00–6.00 mm |
| wall thickness (t_{w}) | 0.05–0.25 mm | 1.00–3.00 mm |
| base thickness (t) | 0.50–1.00 mm | 1.00–3.00 mm |
| basal area of heat | slightly (1x–2x) larger | slightly (1x–2x) larger |
| exchanger (footprint) | than die size | than die size |

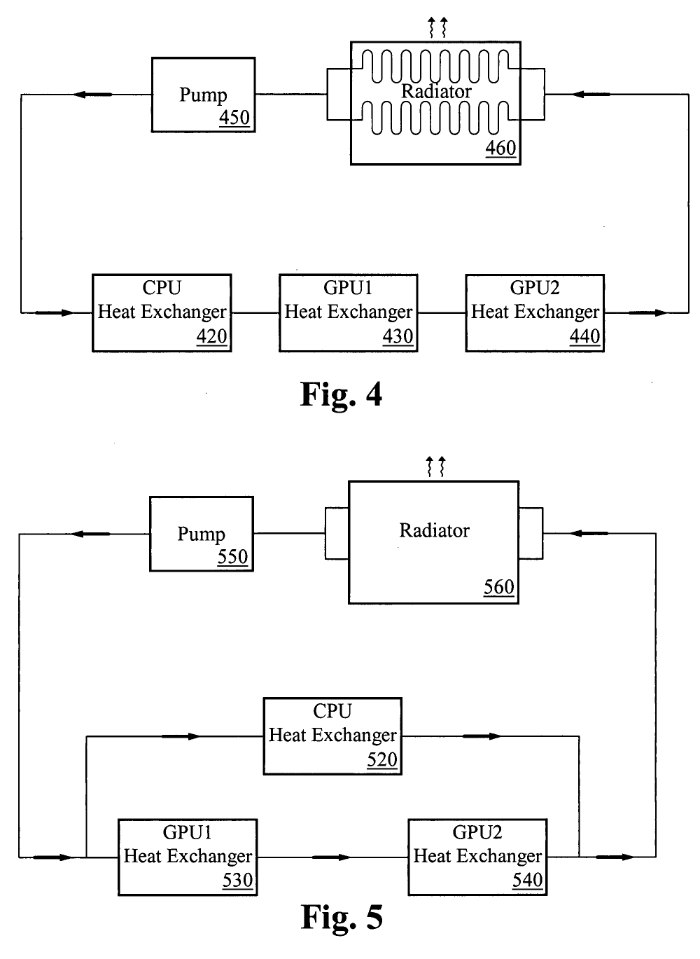

Additionally, some embodiments advantageously maintain and/or lower the operating temperature within the chassis that houses the heat sources. These embodiments typically operate regardless of the number of heat sources, and without the need for extensive modifications to the enclosing chassis. To effect cooling of each heat source and the interior of the chassis, these embodiments couple the various elements of the cooling system, including the cooling module, in a variety of closed loop flow networks. FIGS. 4, 5, 6 and 7 illustrate some examples of some flow network loop options for multi chip and/or multi device cooling. As shown in these figures, for cooling multiple heat sources, a connection between a first heat exchanger and a second heat exchanger is organized such that the first heat exchanger is either in series or in parallel with the second heat exchanger. The connection is formed by using tubing. For instance, FIGS. 4-7 illustrate three cooling plate type heat exchangers in various series and/or parallel configurations. The heat exchangers are coupled with tubing to form the various configurations and are specifically adapted for mounting on each type of heat source, such as a particular semiconductor device type of heat source, for example.

More specifically, FIG. 4 conceptually illustrates a closed cooling loop with three heat exchangers 420, 430, and 440 coupled in series with a pump 450 and a radiator 460. As shown in this figure, the radiator 460 optionally has parallel inputs and outputs for a set of separate radiator elements within a single radiator housing, as described above. Preferably the radiator 460 escrimplemented with a separate or an integrated fan that is capable of moving air at a rate of at least 50-60 cubic feet per minute. As shown in this figure, each heat exchanger is coupled to a particular heat source, such as a central processing unit (CPU) and two graphics processing units (GPUs), to provide optimized cooling to the coupled heat source device. The serial implementation illustrated in FIG. 4 has the advantage of requiring no flow balancing. However, heated fluid flows from the first and second heat exchangers to the downstream heat exchanger(s). Thus, the cooling performance for the downstream device(s) is affected by the upstream devices.

Accordingly, some embodiments order the sequential heat exchangers in a preferred sequence based on a typical maximum operating temperature for each heat source and/or the heat dissipated by each heat source. For instance, for a system configuration having three heat sources: a CPU, a GPU, and a voltage regulator module (VRM), some embodiments preferentially select the following sequence:

| Preferred | Heat | Average | Maximum Operating |
|---|---|---|---|
| Sequential Order | Source | Power Consumption | Temperature |
| 1 | CPU | 100–150 Watts | 70° C. |
| 2 | GPU | 110–200 Watts | 105° C. |
| 3 | VRM | 10–50 Watts | 120° C. |

As shown above, the heat source that is capable of operation at (of “tolerating”) the most amount of heat, which in this case is the VRM, is placed last in the sequential ordering for heat collection, while the least heat tolerant device, the CPU, is placed first. The preferred sequential ordering of the heat exchangers of some embodiments, tends to optimize the cooling efficiency of the closed cooling loop of these embodiments. What is considered optimal, will typically vary by configuration. For instance, it is notable that the GPU of this example, which consumes and/or dissipates the most amount of power, is preferably placed in the middle of the sequence, in deference to the CPU's lower heat tolerance, and in precedence to the VRM's higher heat tolerance. Moreover, heat sources that have higher heat tolerances and that are placed downstream in the sequence for heat absorption do not necessarily require as finely tuned heat collection capability. Instead, the downstream heat exchangers often comprise more “gross” or “macro” cooling structures in comparison to the less tolerant upstream heat sources and/or their associated more finely tuned heat exchangers.

As another example, FIG. 5 conceptually illustrates two series heat exchangers 530 and 540 in parallel with a third heat exchanger 520. As shown in this figure, the two series heat exchangers 530 and 540 are coupled to two graphics processors, while the third heat exchanger 520 is coupled to a central processing unit. As is known in the art, graphics processors typically operate at a higher temperature than CPU's. Hence, the embodiment illustrated in FIG. 5 separates the CPU cooling path from the GPU cooling path, such that the temperature of the fluid cooling the CPU does not directly affect the temperature of the fluid cooling the GPU's, and conversely, the temperature of the fluid cooling the GPU's does not directly affect the temperature of the fluid cooling the CPU. However, as also shown in this figure, one GPU heat exchanger 540 is downstream from another GPU heat exchanger 530. Accordingly, some embodiments configure the cooling paths differently.

FIG. 6 conceptually illustrates a closed cooling loop with a heat exchanger 620 in series with two parallel heat exchangers 630 and 640. As shown in this figure, the series heat exchanger 620 is coupled to a CPU, while the parallel heat exchangers 630 and 640 are coupled to GPUs. In the embodiment illustrated in FIG. 6, the CPU heat exchanger 620 is upstream from the GPU heat exchangers 630 and 640. Since, the CPU typically operates at lower heat than the GPU's, the fluid exiting the CPU heat exchanger 620, still provides cooling efficacy to the downstream GPU heat exchangers 630 and 640. However, in these embodiments and as mentioned above, the cooling properties of the downstream heat exchangers are affected by the upstream heat exchanger(s). Accordingly, some embodiments provide separate cooling loops for the heat exchangers. These embodiments further provide parallel configurations for similar heat exchangers.

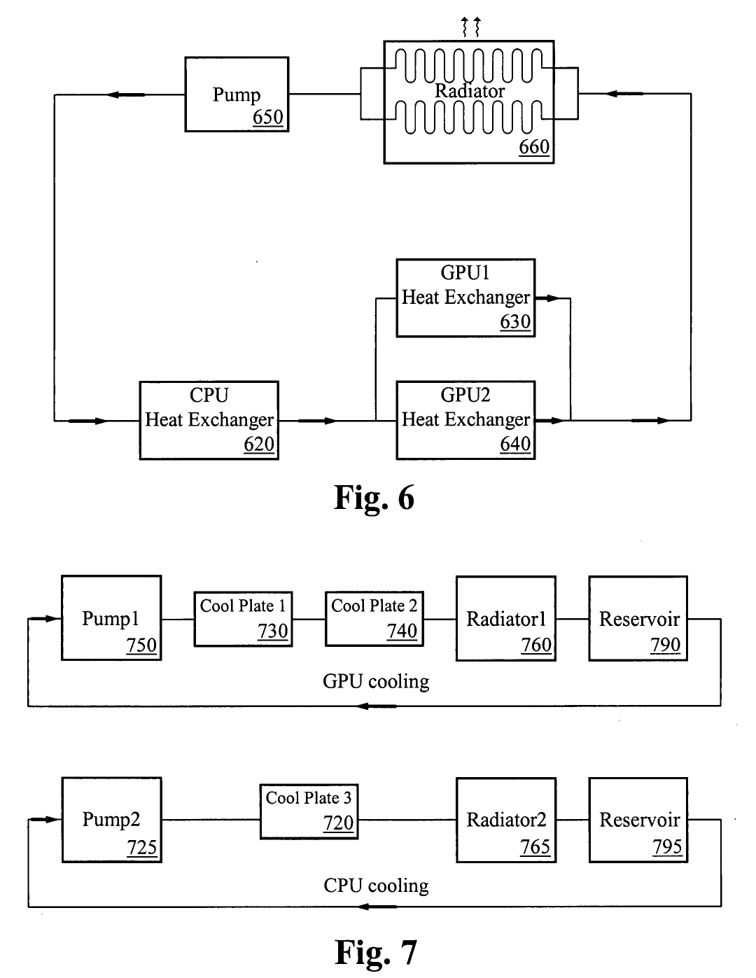

In particular, FIG. 7 conceptually illustrates two separate closed cooling loops, one for GPU cooling and the other for CPU cooling. As shown in this figure, each closed cooling loop includes a pump 750 and 755, a radiator 760 and 765, and a reservoir 790 and 795. Two heat exchangers 730 and 740 (in the form of cooling plates) are coupled to the first loop, and one heat exchanger 720 is coupled to the second loop such that the heat exchangers 720, 730, and 740 provide independent cooling to each loop. Moreover, the heat exchangers 730 and 740 of some embodiments for the two GPUs are disposed in parallel (rather than the illustrated series implementation) to distribute the cooled fluid to the two GPUs in a roughly equal manner.

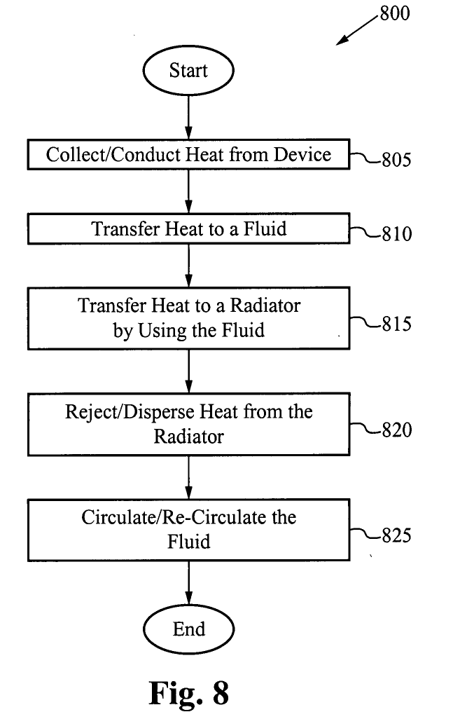

Some embodiments provide a method of cooling a multi device architecture. FIG. 8 is a process flow 800 illustrating the steps of some of these embodiments. As shown in this figure, the process 800 begins at the step 805, where the heat from a first heat source is collected in a first heat exchanger. As described above, the first heat exchanger typically has a fluid and is disposed in intimate contact with the first heat source. Preferably, the first heat exchanger is customized for the first heat source, such as, for example, by optimizing the fluid flow for the maximized conduction of heat for the device. The customization typically includes heat conduction and/or mounting configuration optimization for a particular device, such as, a high performance processor, for example. Once the heat is collected from the device at the step 805, the process 800 transitions to the step 810, where the heat is transferred to the fluid. Then, the process 800 transitions to the step 815.

At the step 815, the heat is transferred to a radiator by using the fluid, and the process 800 transitions to the step 820. At the step 820, the heat is dispersed or rejected from the radiator and then, at the step 825, the cooled fluid is circulated and/or re-circulated through the system. After the step 825, the process 800 concludes. The (re)circulation of the fluid is typically performed by using a pump. Optionally, excess fluid is stored in a reservoir, which also preferably compensates for any loss of fluid over time.

Operation and Performance

Several experiments were conducted for some of the processor configurations described above to produce cooling efficacy data. For instance, an exemplary system having two GPU's and one CPU, achieved approximately 535 Watts of total cooling while displacing air at about 50-60 cubic feet per minute. In this experiment, the junction-to-ambient (Rⱼ₋ₐ) heat resistance was approximately 0.35 degrees Celsius per Watt (° C./Watt) for the upstream and downstream GPU's, while each GPU generated about 185 Watts of heat during operation. Also in this experiment, the case-to-ambient heat resistance (R_{c-a}) was approximately 0.20-0.25° C./Watt at about 165 Watts, for the CPU.

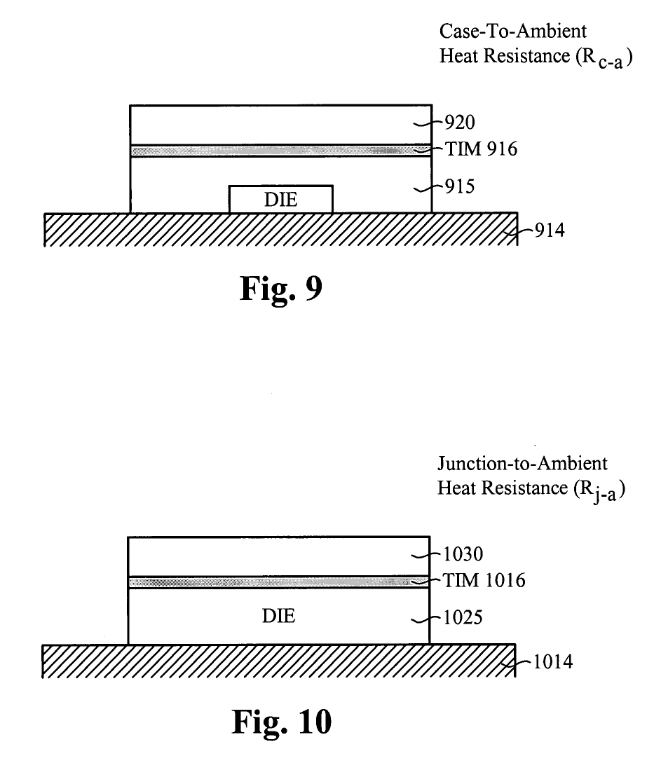

As is known in the art, CPU's typically have a casing, also commonly known as a heat “spreader” that is applied over the top of the semiconductor die during manufacture. Thus, the case-to-ambient heat resistance (R_{c-a}) indicates the maximum amount of heat, measured from the casing of the CPU to the ambient environment (air) outside of the CPU device, that is tolerated by the system. FIG. 9 illustrates such a CPU 915 that is coupled to a heat exchanger 920 for cooling, according to the experiment described above. As shown in this figure, the CPU 915 has a die and a heat spreader, and is typically located on a board 914, such as a printed circuit board, for example. The heat spreader of the CPU 915 is thermally bonded to the heat exchanger 920 by using a thermal insulation material (TIM) 916. The TIM 916 typically comprises an inorganic material such as Iridium or a metallic coat, and/or an organic material such as a thermal grease, a thermal pad, and/or a phase change material, for example.

Since GPU's typically have a “bare” die, the junction-to-ambient (Rⱼ₋ₐ) heat resistance indicates the maximum amount of heat, measured from the surface of the die (at the semiconductor junctions) to the ambient environment (air) immediately adjacent to the surface of the die, that is tolerated by the system. FIG. 10 illustrates an exemplary GPU 1025 that is coupled to a heat exchanger 1030, in accordance with the experiment described above. As shown in this figure, the GPU 1025 is also typically mounted on a circuit board 1014, and has a bare die with no heat spreader. Hence, the TIM 1016 instead bonds the heat exchanger 1030 directly to the surface coating of the die.

Thus, in the implementations illustrated in FIGS. 9 and 10, the cooling system provides improved performance over traditional methods for each processor in a multiprocessor configuration. For instance, the operating temperature for each processor is increased, which is particularly useful for a multiprocessor configuration since each processor contributes to the overall operating environment for all the processors. Typically, the operating specification for a multi processor architecture limits the operating temperature of the processor(s) and/or semiconductor devices to an environment having an ambient temperature of about 35° Celsius.

However, during the experimental testing for the embodiments described above, operating limits were increased to about +33° Celsius above the ambient temperature for the CPU. Hence, for an ambient temperature at the typical specification tolerance of approximately 35° Celsius maximum, the operating limit for the CPU was raised to approximately 68° Celsius, or 33° Celsius above the maximum specified ambient temperature. The following table summarizes the empirical data for the embodiment described above:

| | Air flow | Heat Dissipated | | | Heat |
|---|---|---|---|---|---|
| Processor | (cubic feet | (Watts), approx. | (R_{j–a}) | (R_{c–a}) | Resistance |
| Config. | per minute) | Power Consumed | ° C./Watt | ° C./Watt | Over ambient |
| CPU1 | (one cooling | 165 W (100–200 W) | — | 0.20–0.25 | +33–41° C. |
| GPU1 | module for | 185 W (100–200 W) | 0.35 | — | +65–70° C. |
| GPU2 | heat rejection) | 185 W (100–200 W) | 0.35 | — | +65–70° C. |
| Totals for all | 50–60 CFM | 535 W total this config. | | | 100–110° C. total |
| CPU/GPU | | (300–600 W alternatives) | | | operating temp. |

### ADVANTAGES

Preferably, each component of the cooling systems described above is based on a proprietary design, such as the components provided by Cooligy, Inc. of Mountain View, Calif. For instance, the design of cooling plates and related micro and/or macro scale structures (features) is specific to the chip and/or semiconductor device being cooled. More specifically, each GPU 125 and 135 illustrated in FIG. 1 has its own cooling plate design and mounting configuration. Similarly, the CPU 115 of FIG. 1 has its own cooling plate design and mounting configuration.

As is known in the art, graphics processors tend to be larger and run hotter than CPU's and other ASIC's. Hence, the heat exchanger design for GPU's need not be as finely tuned as for CPU's, and does not always require micro cooling structures (such as micro channels), for example. In some embodiments, a heat exchanger having a more “macro” or gross cooling design suffices. In these embodiments, the cooling for the first heat exchanger necessarily differs from the second heat exchanger, and so on. Thus, additional configurations are preferred, such as the CPU-to-GPU serial implementations described above. This is true for configurations having non processor and/or non semiconductor heat sources as well. For instance, for the configuration that includes a CPU, a GPU, and a VRM, as described above, the VRM of some embodiments has a progressively less finely tuned, or more “macro,” cooling structure design.

As another example, the design of the radiator is also customized for each particular implementation. Some embodiments optimize liquid flow through a micro scale tube of the radiator, while some embodiments optimize airflow across the fins.

While the invention has been described with reference to numerous specific details, one of ordinary skill in the art will recognize that the invention can be embodied in other specific forms without departing from the spirit of the invention. For instance, the figures and description often refer to three heat sources and three heat exchangers, one for each heat source. However, additional embodiments include different numbers and types of heat sources in various permutations. Hence, in some embodiments only one or two heat sources are present and/or require a heat exchanger for cooling, while in other embodiments more than three heat sources are housed in a single chassis that requires cooling. Moreover, while the heat sources have been described by using the embodiments above in relation to exemplary semiconductor devices and/or processor chips, other types and forms of heat sources are contemplated as well, including non semiconductor type heat sources, for example. Thus, one of ordinary skill in the art will understand that the invention is not to be limited by the foregoing illustrative details, but rather is to be defined by the appended claims.

What is claimed is:

1. A cooling system for cooling an electronic system in a chassis, comprising:
a. a first heat exchanger thermally coupled to a first heat source;
b. a second heat exchanger thermally coupled to a second heat source;
c. a fluid flowing through the first and second heat exchangers;
d. a first pump for driving the fluid;
e. a first radiator a first fan to reject heat from the first radiator; and
f. tubing that interconnects the first heat exchanger, the second heat exchanger, the first pump, and the first radiator, wherein the cooling system is mounted substantially interior of an upper surface of the chassis such that the first fan blows air through the first radiator and exterior of the chassis, and further wherein up to 600 W of heat is removed from the chassis while producing no more than 35 dB of noise.

2. The cooling system of claim 1 further comprising a third heat exchanger coupled to a third heat source.

3. The cooling system of claim 1, wherein the first heat exchanger comprises a micro scale cold plate.

4. The cooling system of claim 1, wherein the first heat exchanger comprises a micro channel.

5. The cooling system of claim 1, wherein the tubing is designed to minimize fluid loss.

6. The cooling system of claim 1, further comprising a coupling between the first heat exchanger and the second heat exchanger, wherein the coupling is such that the first and second heat exchangers are in series.

7. The cooling system of claim 1, wherein the first heat exchanger and the second heat exchanger are in parallel.

8. The cooling system of claim 1, further comprising a second radiator, a second pump, and a second fan wherein the cooling system is mounted such that the second fan blows air through the second radiator and exterior of the chassis.

9. The cooling system of claim 1, wherein the second heat source comprises a graphics processing unit (GPU).

10. The cooling system of claim 1, wherein the first heat source comprises a central processing unit (CPU).

11. The cooling system of claim 1, wherein the cooling module is organized into a slim low profile assembly, with a maximum height of approximately 120 millimeters, wherein the length and width of the assembly are smaller than the dimensions of a computer chassis.

12. A cooling system for cooling an electronic system in a chassis, comprising:
a first cooling plate adapted for use with a first processor;
a second cooling plate adapted for use with a second processor;
a tubing for interconnecting the cooling plates;
a fluid flowing through the cooling plates and the tubing;
a radiator for conducting heat from the fluid; and
a first pump for driving the fluid through the tubing and the cooling plates to the radiator
wherein the cooling system is mounted substantially interior of an upper surface of the chassis such that the first fan blows air through the radiator and exterior of the chassis, and further wherein up to 600 W of heat is removed from the chassis while producing no more than 35 dB of noise.

13. The cooling system of claim 12 further comprising a reservoir for storing the fluid.

14. The cooling system of claim 12 further comprising a third cooling plate adapted for use with a third heat source.

15. The cooling system of claim 12, wherein the module has a top exhaust and a side intake.

16. The cooling system of claim 12, wherein a volumetric air displacement for the system is approximately 50-60 cubic feet per minute.

17. The cooling system of claim 12, wherein the junction-to-ambient resistance (Rⱼ₋ₐ) is no more than 0.3 degrees Celsius per Watt for the each processor.

18. The cooling system of claim 12, wherein the system comprises:
a first cooling loop; and
a second cooling loop.

19. The cooling system of claim 12, wherein the radiator further comprises:
a micro tube; and
air fins.

20. The cooling system of claim 12, wherein the design of the radiator is customized for the application of the cooling system, wherein the design further comprises one or more of:
an optimized liquid flow through a micro tube; and
an optimized airflow across one or more air fins.
